(19) United States
(12) Patent Application Publication
(10) Pub. No.: US 2025/0238025 A1
(43) Pub. Date: Jul. 24, 2025

(54) INFORMATION PROCESSING APPARATUS, INFORMATION PROCESSING METHOD, AND STORAGE MEDIUM

(71) Applicant: Tokyo Electron Limited, Tokyo (JP)

(72) Inventors: Ryota AOI, Hokkaido (JP); Nobutoshi TERASAWA, Hokkaido (JP)

(21) Appl. No.: 19/026,799

(22) Filed: Jan. 17, 2025

(30) Foreign Application Priority Data
Jan. 24, 2024 (JP) 2024-008755
Nov. 5, 2024 (JP) 2024-193819

(51) Int. Cl. G05B 19/418; G06T 11/20

(52) U.S. Cl. CPC G05B 19/41855; G06T 11/206; G05B 2219/31151; G05B 2219/32128; G05B 2219/45031; G06T 2200/24

(57) ABSTRACT

An information processing apparatus that displays operation statuses of one or more substrate processing apparatuses. The information processing apparatus includes: an acquisition unit that acquires history information of a plurality of apparatus states to which the plurality of substrate processing apparatuses have transitioned; and a display control unit that displays time zones during which the substrate processing apparatuses were in the plurality of apparatus states, in chronological order, based on the acquired history information such that each of the apparatus states is identifiable.

### CROSS-REFERENCE TO RELATED APPLICATION

This application is based on and claims priority from Japanese Patent Application Nos. 2024-008755 and 2024-193819, filed on Jan. 24, 2024 and Nov. 5, 2024, respectively, with the Japan Patent Office, the disclosures of which are incorporated herein in their entireties by reference.

### TECHNICAL FIELD

The present disclosure relates to an information processing apparatus, an information processing method, and a storage medium.

### BACKGROUND

In the related art, in order to allow a user to easily grasp an idle state of a substrate processing apparatus, a technique has been known in which a first idle time indicating a time during which no processing is being performed and a second idle time indicating a time from the end of a job to the start of execution of the following job are calculated based on first history information of a processing executed by the substrate processing apparatus, and second history information of job execution instructions received, and the first idle time and the second idle time are displayed (see e.g., Japanese Patent Laid-Open Publication No. 2022-134502).

### SUMMARY

According to an aspect of the present disclosure, an information processing apparatus displays operation statuses of one or more substrate processing apparatuses. The information processing apparatus includes: an acquisition unit that acquires history information of a plurality of apparatus states to which the plurality of substrate processing apparatuses have transitioned; and a display control unit that displays time zones during which the plurality of substrate processing apparatuses were in the apparatus states, in chronological order, based on the acquired history information such that each of the apparatus states is identifiable.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a configuration diagram of an example of a substrate processing system according to the present embodiment.

FIG. 2 is a hardware configuration diagram of an example of a computer.

FIG. 3 is a functional block diagram illustrating an example of an operator terminal according to the present embodiment.

FIG. 4 is a flowchart of an example of processing in which the operator terminal according to the present embodiment displays the operation statuses of one or more substrate processing apparatuses.

FIG. 5 is an image view of an example of a tool board screen.

FIG. 6 is an image view of an example of an operation analysis screen.

FIG. 7 is a view of an example in which the coloring of a portion indicating the alarm state of a chart is explained.

FIG. 8 is a view illustrating an example of a tooltip display.

FIG. 9 is a view illustrating an example of an alarm log list display.

FIG. 10 is a view of an example in which a change of display settings of the chart is explained.

FIG. 11 is a view illustrating an example of the display setting of scrolling.

FIG. 12 is a view illustrating an example of the display setting of a scale interval.

FIG. 13 is a view illustrating an example of the display setting of a display unit.

FIG. 14 is a view illustrating an example of apparatus addition.

FIG. 15 is a view illustrating an example of the chart in which a plurality of substrate processing apparatuses is added.

FIG. 16 is a view illustrating an example of the chart in which different periods are specified for the substrate processing apparatuses.

FIG. 17 is a view illustrating an example of apparatus deletion.

FIG. 18 is a view illustrating an example of a period change.

FIG. 19 is a view illustrating an example of starting point adjustment.

FIG. 20 is a view illustrating an example of starting point adjustment.

FIG. 21 is a view illustrating an example of starting point adjustment.

FIG. 22 is a view illustrating an example of starting point adjustment.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, the present embodiment will be described with reference to drawings.

### System Configuration

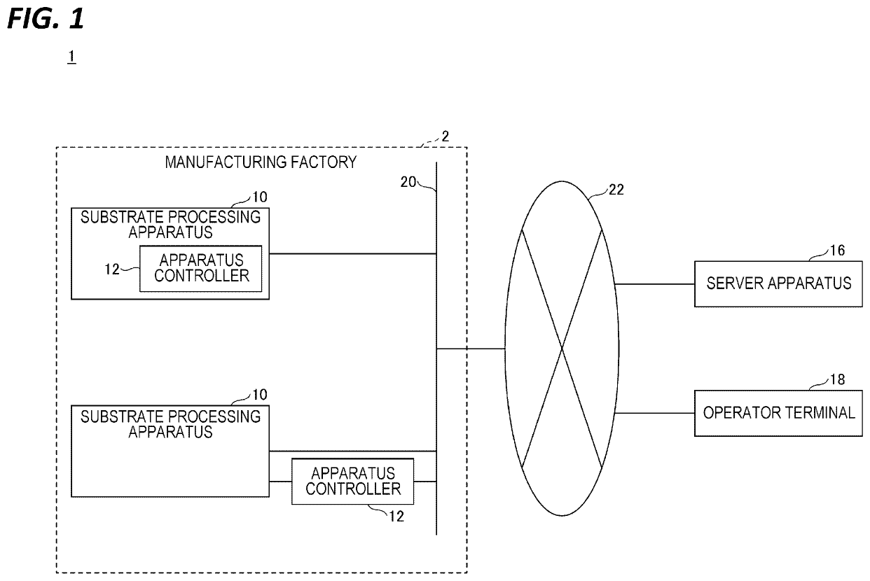

FIG. 1 is a configuration diagram of an example of a substrate processing system 1 according to the present embodiment. The substrate processing system 1 illustrated in FIG. 1 includes a substrate processing apparatus 10, an apparatus controller 12, a server apparatus 16 and an operator terminal 18.

The substrate processing apparatus 10 and the apparatus controller 12 are installed in a manufacturing factory 2. The server apparatus 16 and the operator terminal 18 may be installed in the manufacturing factory 2, or may be installed in a place other than the manufacturing factory 2. The operator terminal 18 is an information processing terminal such as a personal computer (PC) or a smart phone, which is operated by an operator of the substrate processing apparatus 10 installed in the manufacturing factory 2, such as the person in charge of equipment or the person in charge of an analysis.

The substrate processing apparatus 10, the apparatus controller 12, the server apparatus 16 and the operator terminal 18 are communicatively connected via networks 20 and 22 such as the Internet or the local area network (LAN).

The substrate processing apparatus 10 is an apparatus that performs a processing such as a film forming processing, an etching processing, or an ashing processing, on a substrate such as, for example, a semiconductor wafer. The substrate processing apparatus 10 is, for example, a semiconductor manufacturing apparatus, a heat treatment apparatus, or a film formation apparatus.

The substrate processing apparatus 10 receives, for example, a control command (e.g., a setting value) according to a recipe from the apparatus controller 12, and executes a process. The substrate processing apparatus 10 is provided with a plurality of sensors such as a temperature sensor for measuring a temperature and a pressure sensor for measuring a pressure.

The apparatus controller 12 receives instructions for the substrate processing apparatus 10, from the operator. The apparatus controller 12 has a function of a man-machine interface that provides the operator with information related to the substrate processing apparatus 10. The apparatus controller 12 receives sensor data output from the plurality of sensors provided in the substrate processing apparatus 10. The apparatus controller 12 may optimize the setting values of the substrate processing apparatus 10, detect abnormalities, or predict abnormalities.

Also, the apparatus controller 12 may save the history information (e.g., log information) of the substrate processing apparatus 10 required to display the operation status of the substrate processing apparatus 10 as described below. For example, history information of a plurality of apparatus states, history information of process job states, and history information of alarm states may be saved in the history information of the substrate processing apparatus 10 required to display the operation status of the substrate processing apparatus 10 as described below.

The apparatus controller 12 illustrated in FIG. 1 is provided for each substrate processing apparatus 10, but may be provided for a plurality of substrate processing apparatuses 10. The apparatus controller 12 may be provided inside the casing of the substrate processing apparatus 10, or may be provided outside the casing.

Also, the server apparatus 16 may receive and save information related to the plurality of substrate processing apparatuses 10 of one or more manufacturing factories 2. For example, the server apparatus 16 saves the history information of the substrate processing apparatuses 10 required to display the operation statuses of the plurality of substrate processing apparatuses 10 of one or more manufacturing factories 2 as described below.

The server apparatus 16 may have a man-machine interface function for providing information about the substrate processing apparatus 10 to the operator by using, for example, a Web application. Also, the server apparatus 16 may have a man-machine interface function for displaying the operation status of the substrate processing apparatus 10 by using, for example, a Web application.

The operator terminal 18 may save, for example, the history information of the plurality of apparatus states required to display the operation statuses of the plurality of substrate processing apparatuses 10 of one or more manufacturing factories 2 as described below. The operator terminal 18 may have a man-machine interface function for displaying information about the substrate processing apparatus 10 by using, for example, a Web application. Also, the operator terminal 18 may have a man-machine interface function for displaying the operation status of the substrate processing apparatus 10 by using, for example, a Web application.

The apparatus controller 12 and the server apparatus 16 may display the information related to the substrate processing apparatus 10 and the operation statuses of the plurality of substrate processing apparatuses 10, on the operator terminal 18. The apparatus controller 12, the server apparatus 16, and the operator terminal 18 illustrated in FIG. 1 are examples of the information processing apparatus according to the present embodiment.

The substrate processing system 1 illustrated in FIG. 1 is an example, and it goes without saying that there are various system configuration examples depending on the use and purpose. The distinction between apparatuses illustrated in FIG. 1, that is, the distinction between the apparatus controller 12, the server apparatus 16 and the operator terminal 18, is an example. For example, it is possible to obtain various configurations such as a configuration in which at least two of the apparatus controller 12, the server apparatus 16 and the operator terminal 18 are integrated, and a subdivided configuration.

### Hardware Configuration

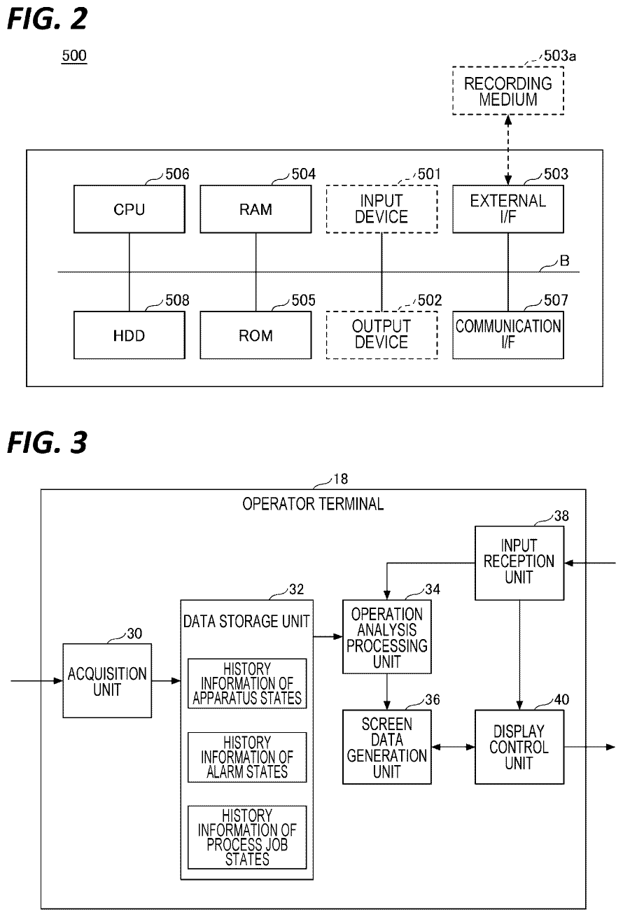

The apparatus controller 12, the server apparatus 16, and the operator terminal 18 illustrated in FIG. 1 may be implemented by, for example, computers having a hardware configuration illustrated in FIG. 2. FIG. 2 is a hardware configuration diagram of an example of a computer 500.

The computer 500 of FIG. 2 includes, for example, an input device 501, an output device 502, an external I/F (interface) 503, a random access memory (RAM) 504, a read only memory (ROM) 505, a central processing unit (CPU) 506, a communication I/F 507 and a hard disk drive (HDD) 508, which are connected to each other via a bus B. In the form of the input device 501 and the output device 502, these may be connected and used as necessary.

The input device 501 is, for example, a keyboard, a mouse, or a touch panel, and is used when the operator inputs an operation signal. The output device 502 is, for example, a display, and displays the results of processing by the computer 500. The communication I/F 507 is an interface that connects the computer 500 to the networks 20 and 22 illustrated in FIG. 1. The HDD 508 is an example of a non-volatile storage device that stores programs or data.

The external I/F 503 is an interface with an external device. The computer 500 may read a recording medium 503a such as a secure digital (SD) memory card via the external I/F 503. The computer 500 may be able to write to the recording medium 503a such as an SD memory card via the external I/F 503.

The ROM 505 is an example of a non-volatile semiconductor memory (storage device) in which programs and data are stored. The RAM 504 is an example of a volatile semiconductor memory (storage device) that temporarily holds programs and data. The CPU 506 is a calculation device that reads programs and data from a storage device such as the ROM 505 or the HDD 508, on the RAM 504, and executes processing, thereby implementing the overall control and functions of the computer 500.

The apparatus controller 12, the server apparatus 16 and the operator terminal 18 of the substrate processing system 1 illustrated in FIG. 1 implement various functions by executing programs, on the computer 500 illustrated in FIG. 2.

### Functional Configuration

Hereinafter, descriptions will be made on an example in which an information processing apparatus displaying the operation statuses of one or more substrate processing apparatuses 10 is the operator terminal 18. The information processing apparatus displaying the operation statuses of one or more substrate processing apparatuses 10 may be the apparatus controller 12 or the server apparatus 16.

The operator terminal 18 of the substrate processing system 1 according to the present embodiment is implemented by, for example, functional blocks as illustrated in FIG. 3. FIG. 3 is a functional block diagram illustrating an example of the operator terminal 18 according to the present embodiment. In the functional block diagram of FIG. 3, components unnecessary for the explanation of the present embodiment are omitted in the illustration.

The operator terminal 18 of FIG. 3 implements an acquisition unit 30, a data storage unit 32, an operation analysis processing unit 34, a screen data generation unit 36, an input reception unit 38, and a display control unit 40 by executing a program for the operator terminal 18.

The acquisition unit 30 acquires the history information of the substrate processing apparatus 10 required to display the operation status of the substrate processing apparatus 10 as described below. The acquisition unit 30 may acquire the history information of the substrate processing apparatus 10 from the substrate processing apparatus 10, from the apparatus controller 12, from the server apparatus 16.

The history information of the substrate processing apparatus 10 acquired by the acquisition unit 30 includes, for example, history information of a plurality of apparatus states, history information of process job states and history information of alarm states. The acquisition unit 30 stores the acquired history information of the substrate processing apparatus 10, in the data storage unit 32.

The input reception unit 38 receives various operations from the operator. For example, the operations received from the operator include, for example, an operation for starting an application, and various operations for the started application. The input reception unit 38 notifies the operation analysis processing unit 34 and the display control unit 40 of the contents of the various operations received from the operator.

The operation analysis processing unit 34 reads the history information of the substrate processing apparatus 10 from the data storage unit 32 based on the contents of the various operations received from the operator, and analyzes the operation status of the substrate processing apparatus 10 to be described below.

The screen data generation unit 36 generates screen data including the results of the analysis by the operation analysis processing unit 34, and transmits the screen data to the display control unit 40. The display control unit 40 displays the screen data including the results of the analysis by the operation analysis processing unit 34, on the output device 502.

### Processing

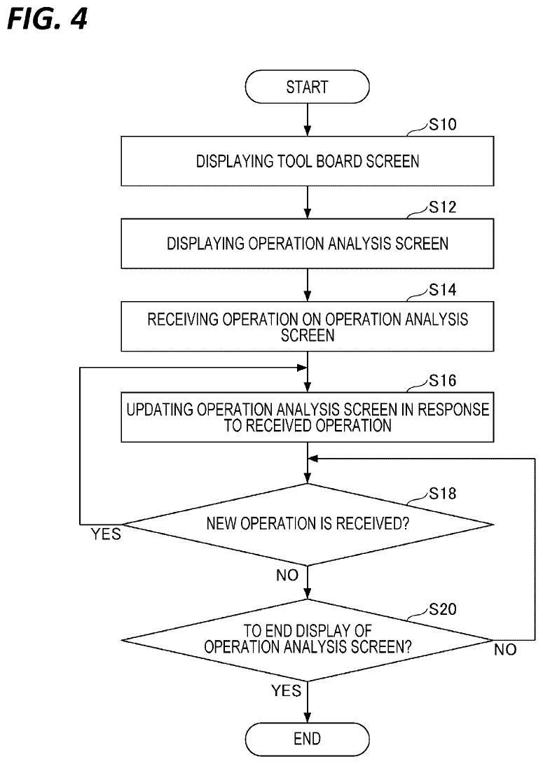

The operator terminal 18 displays the operation statuses of one or more substrate processing apparatuses 10 according to, for example, the processing procedure illustrated in FIG. 4. FIG. 4 is a flowchart of an example of processing in which the operator terminal 18 according to the present embodiment displays the operation statuses of one or more substrate processing apparatuses 10.

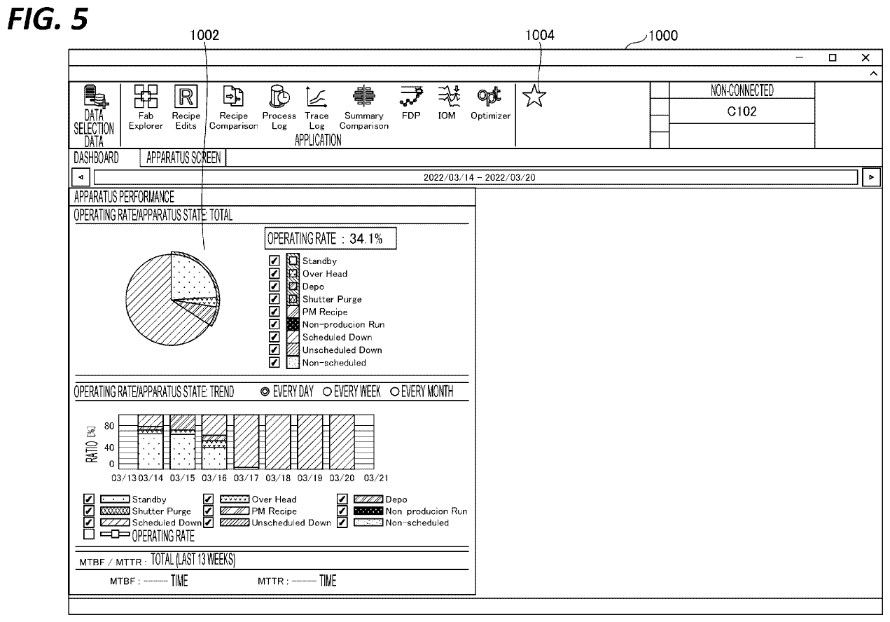

In the step S10, the display control unit 40 of the operator terminal 18 displays, for example, a tool board screen 1000 illustrated in FIG. 5, on the output device 502, based on the contents of operations received from the operator. FIG. 5 is an image view of an example of the tool board screen 1000. The tool board screen 1000 illustrated in FIG. 5 displays apparatus performance information 1002 of the substrate processing apparatus 10. On the apparatus performance information 1002, the operation rate, and the total and trend of the ratios of apparatus states are displayed. On the tool board screen 1000 of FIG. 5, as examples of the apparatus states, Standby, Over Head, Depo, Shutter Purge, PM Recipe, Non-production, Scheduled Down, Unscheduled Down and Non-scheduled are described. The apparatus state “Depo” is an example of a state in which the substrate processing apparatus 10 performs manufacturing according to a recipe.

By referring to the apparatus performance information 1002 of the tool board screen 1000 of FIG. 5, the operator may check the operation rate of the substrate processing apparatus 10 and the ratio of each apparatus state, in a specified period.

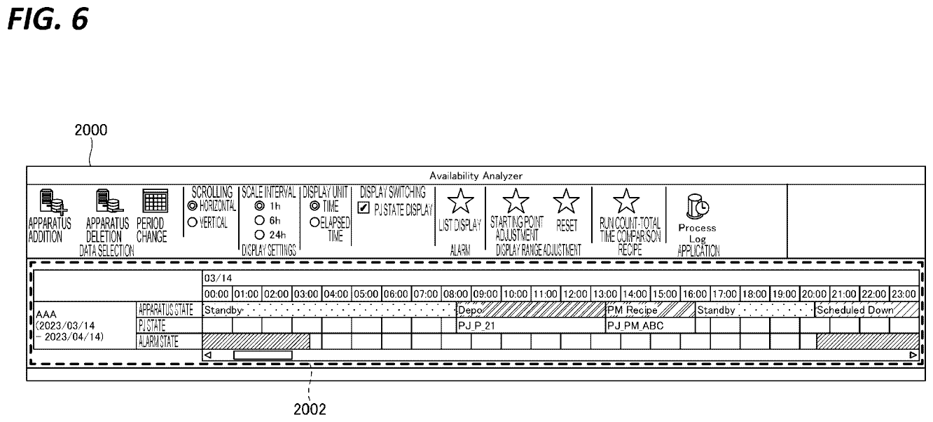

When the operator performs an operation such as clicking on an operation analysis application icon 1004 on the tool board screen 1000, the display control unit 40 displays, for example, an operation analysis screen 2000 as illustrated in FIG. 6.

FIG. 6 is an image view of an example of the operation analysis screen 2000. The operation analysis screen 2000 illustrated in FIG. 6 displays a chart 2002. The chart 2002 displays the specified period and the operation status of the substrate processing apparatus 10, i.e., a plurality of apparatus states, process job (PJ) states and alarm states in chronological order.

The plurality of apparatus states may be generated from the history information of the plurality of apparatus states to which the substrate processing apparatus 10 has been subjected. In the portion of the chart 2002 indicating the apparatus states, time zones during which the substrate processing apparatus 10 was in the apparatus states are displayed, and the time zones are visually distinguished by, for example, colors such that each apparatus state may be identified. In the portion of the chart 2002 indicating the process job states, the time zones during which the substrate processing apparatus 10 was executing process jobs are displayed such that each process job may be identified. In the portion of the chart 2002 indicating the alarm states, the time zones during which alarms were occurring in the substrate processing apparatus 10 (periods during which uncancelled alarms were present) are displayed.

An alarm for the substrate processing apparatus 10 is issued when a specific event has occurred in the substrate processing apparatus 10. The alarm is used to allow, for example, the operator to identify a problem part of the substrate processing apparatus 10.

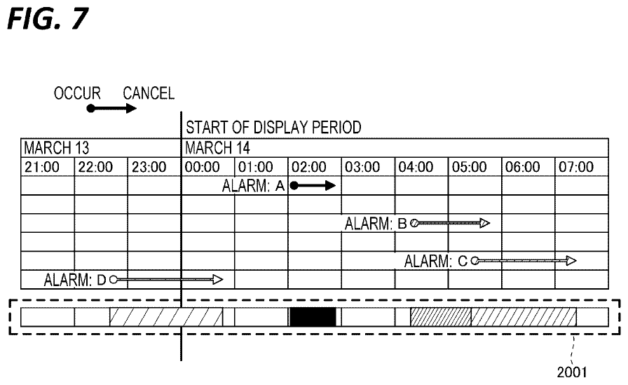

FIG. 7 is a view of an example in which the coloring of a portion 2001 indicating the alarm state of the chart 2002 is explained. As illustrated in FIG. 7, in the portion 2001 indicating the alarm state of the chart 2002, a period from the occurrence to the cancelation of an alarm is colored as a period during which the alarm was occurring. When a plurality of alarms is present, as illustrated in FIG. 7, periods during which one or more alarms were occurring are colored.

FIG. 7 displays the portion 2001 indicating the alarm state of the chart 2002 in an identifiable manner so that the relationship between the issued alarm, and the portion 2001 indicating the alarm state of the chart 2002 may be easily understood. As illustrated in FIG. 7, in the portion 2001 indicating the alarm state of the chart 2002, in the displayed period, time zones during which one or more alarms were occurring are displayed in an identifiable manner through, for example, coloring.

The process returns to the step S14 of FIG. 4, and the operator may perform various operations on the operation analysis screen 2000 of FIG. 6. The input reception unit 38 of the operator terminal 18 receives various operations on the operation analysis screen 2000, from the operator.

In the step S16, the display control unit 40 of the operator terminal 18 updates the operation analysis screen 2000 of FIG. 6 as follows in response to the operations received from the operator.

### Tooltip Display

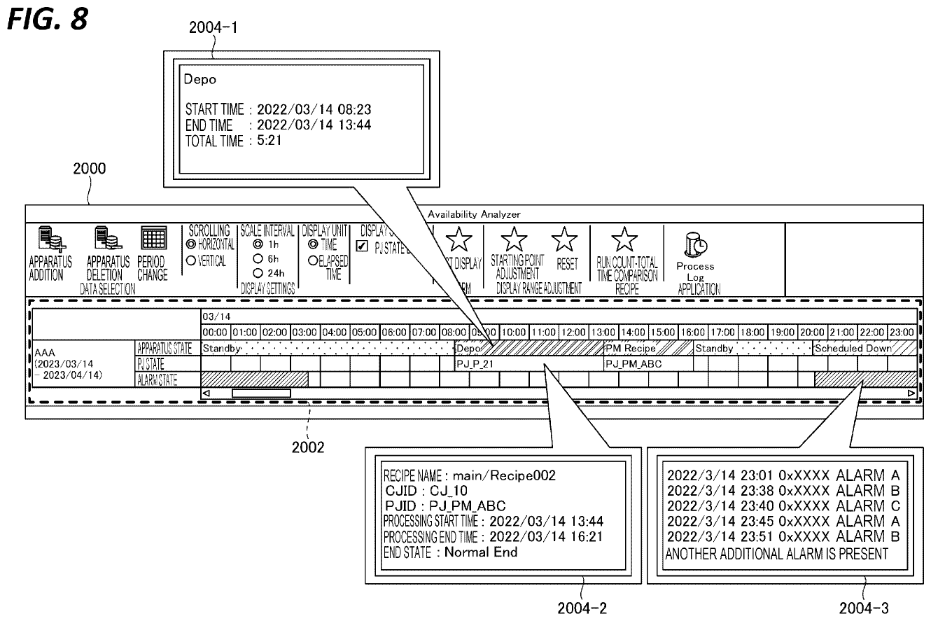

The operator may place, for example, a cursor of a pointing apparatus such as a mouse, on the chart 2002 of the operation analysis screen 2000 of FIG. 6 so as to display, for example, tooltips 2004-1 to 2004-3 illustrated in FIG. 8.

FIG. 8 is a view illustrating an example of a tooltip display. The tooltips 2004-1 to 2004-3 are one of display elements in a graphical user interface of the computer 500, and are displayed when, for example, a cursor is superimposed on a target.

The tooltip 2004-1 is an area that is displayed when, for example, the cursor is superimposed on the portion of the chart 2002 indicating the apparatus states, and information on the apparatus state of the portion superimposed with the cursor is displayed.

Also, the tooltip 2004-2 is an area that is displayed when, for example, the cursor is superimposed on the portion of the chart 2002 indicating the process job states, and information on the process job state of the portion superimposed with the cursor is displayed. Also, the tooltip 2004-3 is an area that is displayed when, for example, the cursor is superimposed on the portion of the chart 2002 indicating the alarm states, and information on the alarm state of the portion superimposed with the cursor is displayed. FIG. 8 illustrates an example in which the tooltips 2004-1 to 2004-3 are displayed at once, but they may be displayed one by one.

In the tooltip display illustrated in FIG. 8, the operator may easily check information for determining the operation status of the substrate processing apparatus 10 by placing, for example, the cursor of the pointing apparatus such as a mouse, on the chart 2002 of the operation analysis screen 2000.

### Alarm log List Display

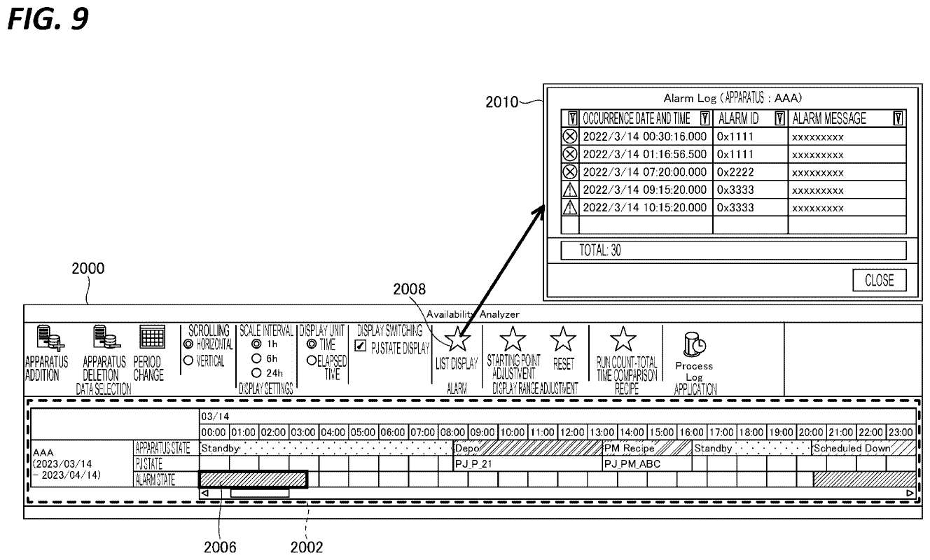

As illustrated in the operation analysis screen 2000 of FIG. 9, the operator may select a part 2006 indicating the alarm state of the chart 2002, and operate a list display button 2008 so as to display an alarm log list 2010 of the part 2006.

FIG. 9 is a view illustrating an example of an alarm log list display. The display control unit 40 of the operator terminal 18 displays the alarm log list 2010 of the part 2006 by receiving an operation of selecting the part 2006 indicating the alarm state of the chart 2002 and an operation of selecting the list display button 2008, from the operator.

### Display Settings

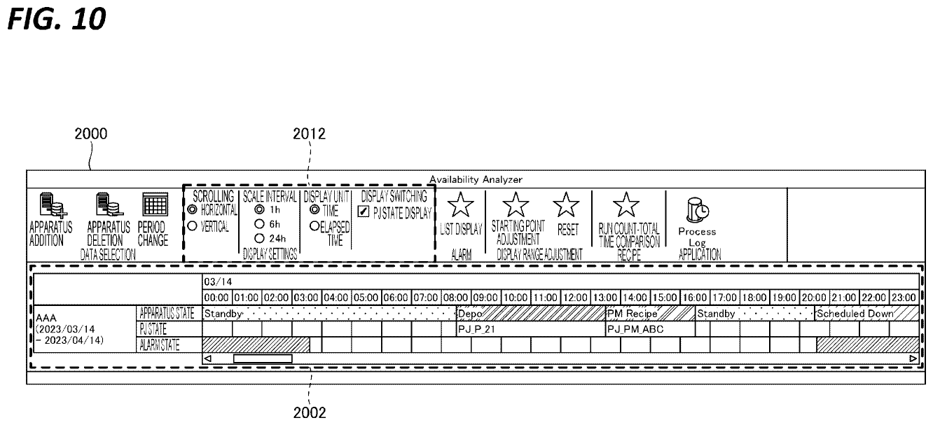

The operator may change display settings of the chart 2002 by operating a display settings field 2012 of the operation analysis screen 2000 of FIG. 10. As illustrated in FIG. 10, the display settings field 2012 of the operation analysis screen 2000 is an example in which display settings of scrolling, scale interval, display unit and display switching are changeable.

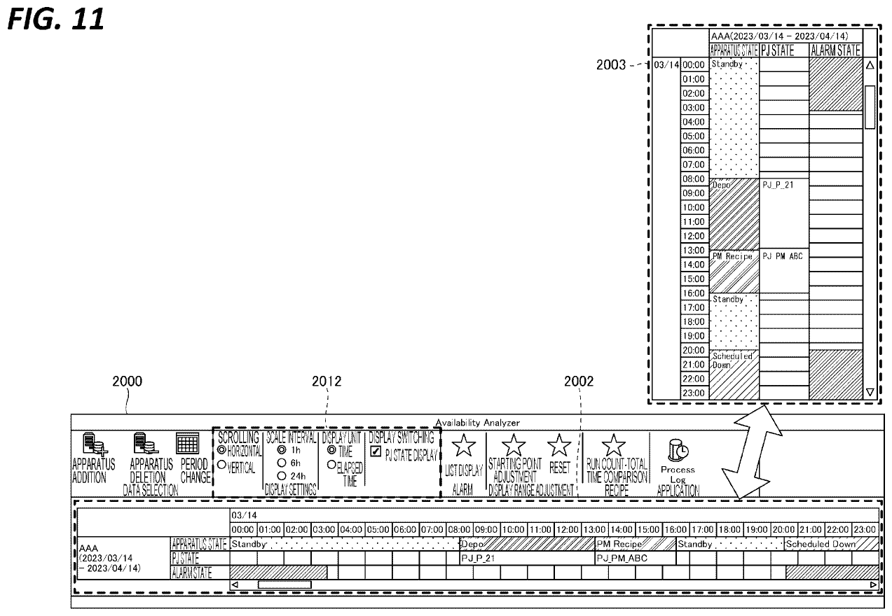

The display setting of the scrolling of the display settings field 2012 will be described by using FIG. 11. FIG. 11 is a view illustrating an example of the display setting of scrolling. The display may be switched to a chart 2003 of vertical scrolling (vertical display) by the display control unit 40 of the operator terminal 18 when the display setting of scrolling in the display settings field 2012 of the operation analysis screen 2000 of FIG. 10 is changed from “horizontal” to “vertical.” Also, the display may be switched to the chart 2002 of horizontal scrolling (horizontal display) by the display control unit 40 of the operator terminal 18 when the display setting of scrolling in the display settings field 2012 of the operation analysis screen 2000 of FIG. 10 is changed from “vertical” to “horizontal.”

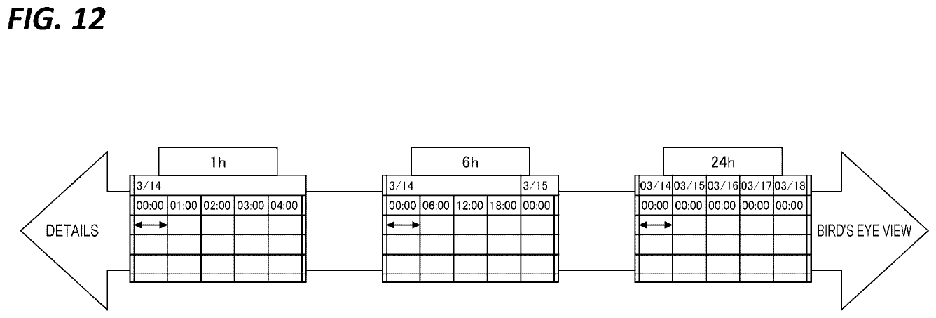

The display setting of the scale interval of the display settings field 2012 will be described by using FIG. 12. FIG. 12 is a view illustrating an example of the display setting of the scale interval. The display control unit 40 of the operator terminal 18 performs switching of the scale interval of the chart 2002 when the display setting of the scale interval in the display settings field 2012 of the operation analysis screen 2000 of FIG. 10 is switched.

For example, a time range per scale mark is switched to a narrow range by the display control unit 40 of the operator terminal 18 when the display setting of the scale interval in the display settings field 2012 of the operation analysis screen 2000 of FIG. 10 is switched to “1 h,” as illustrated in FIG. 12. This allows the operator to check the details of the chart 2002.

Also, a time range per scale mark in the chart 2002 is switched to a wide range by the display control unit 40 of the operator terminal 18 when the display setting of the scale interval in the display settings field 2012 of the operation analysis screen 2000 of FIG. 10 is switched to “24 h”. This allows the operator to check the chart 2002 with a bird's-eye view.

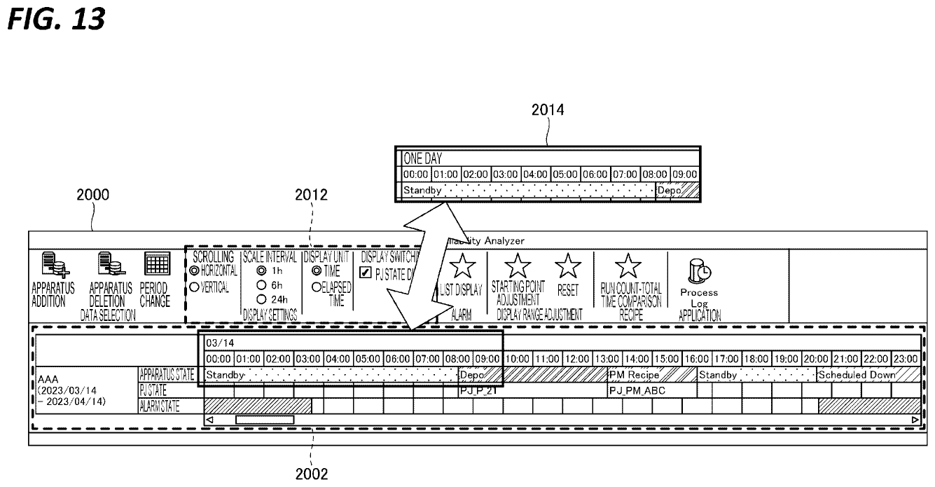

The display setting of the display unit of the display settings field 2012 will be described by using FIG. 13. FIG. 13 is a view illustrating an example of the display setting of the display unit. The display control unit 40 of the operator terminal 18 performs switching of the display unit of the scale of the chart 2002 when the display setting of the display unit of the display settings field 2012 of the operation analysis screen 2000 of FIG. 10 is switched.

For example, as illustrated in FIG. 13, when the display setting of the display unit in the display settings field 2012 of the operation analysis screen 2000 of FIG. 10 is switched to “elapsed time,” the chart 2002 displayed based on the time is switched to a chart 2014 displayed based on the elapsed time by the display control unit 40 of the operator terminal 18. The operator may use the chart 2014 displayed based on the elapsed time in, for example, comparison between the charts 2014 of the substrate processing apparatuses 10.

Also, when the display setting of the display unit in the display settings field 2012 of the operation analysis screen 2000 of FIG. 10 is switched to “time,” the chart 2014 displayed based on the elapsed time is switched to the chart 2002 displayed based on the time by the display control unit 40 of the operator terminal 18.

The display setting of the display switching of the display settings field 2012 will be described by using FIG. 10. When the display setting of the display switching in the display settings field 2012 of the operation analysis screen 2000 of FIG. 10 is switched, a row of the PJ state in the chart 2002 is switched between display and non-display by the display control unit 40 of the operator terminal 18.

For example, when a tick is put in the display setting “PJ state display” of the display switching in the display settings field 2012 of the operation analysis screen 2000 of FIG. 10, as illustrated in FIG. 10, the display control unit 40 of the operator terminal 18 displays the row of the PJ state of the chart 2002. Also, when the tick is canceled from the display setting “PJ state display” of the display switching in the display settings field 2012 of the operation analysis screen 2000 of FIG. 10, the display control unit 40 of the operator terminal 18 hides the row of the PJ state in the chart 2002.

### Apparatus Addition

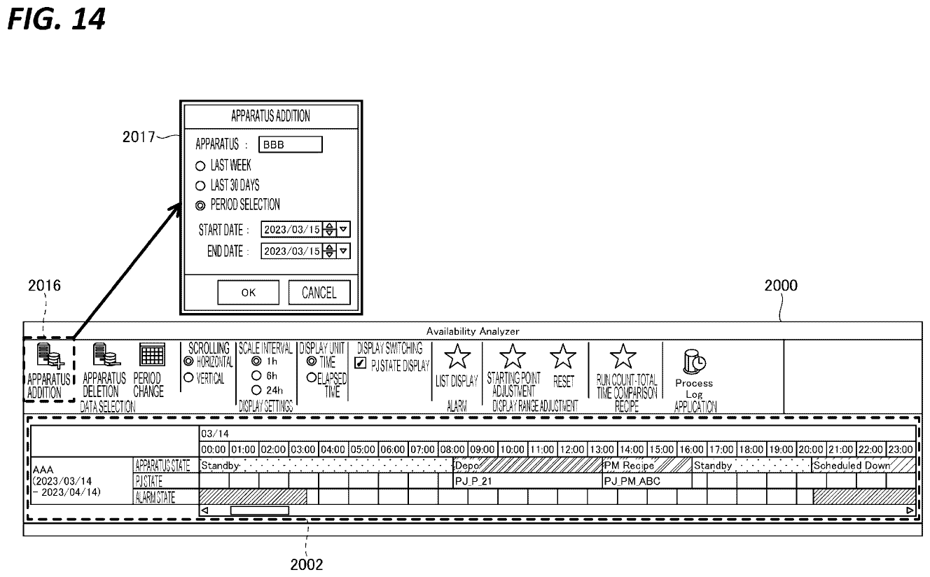

The operator operates an apparatus addition button 2016 on the operation analysis screen 2000 in FIG. 14, thereby displaying an apparatus addition field 2017. The operator may input information required for the apparatus addition field 2017, thereby adding the substrate processing apparatus 10 to be displayed on the chart 2002.

FIG. 14 is a view illustrating an example of apparatus addition. The display control unit 40 of the operator terminal 18 displays the apparatus addition field 2017 by receiving the operation on the apparatus addition button 2016 from the operator. Also, when necessary information is input to the apparatus addition field 2017 from the operator, the display control unit 40 may add the substrate processing apparatus 10 to be displayed on the chart 2002.

In the apparatus addition field 2017 of FIG. 14, it is possible to specify a data range to be displayed, by, for example, the last week, the last 30 days, or period selection. The display control unit 40 adds the chart 2002 of the substrate processing apparatus 10 specified by the operator in the apparatus addition field 2017 of FIG. 14. In the apparatus addition field 2017, a plurality of substrate processing apparatuses 10 may be specified at one time.

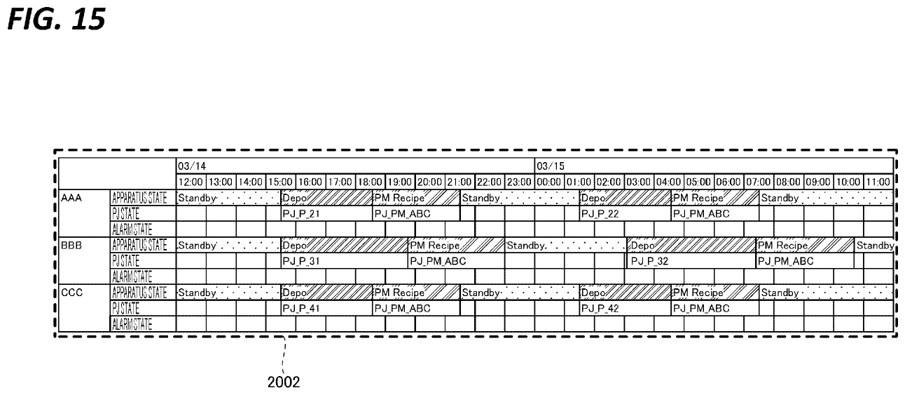

FIG. 15 is a view illustrating an example of the chart 2002 in which the plurality of substrate processing apparatuses 10 is added. As illustrated in FIG. 15, the display control unit 40 of the operator terminal 18 may display the operation statuses of the plurality of substrate processing apparatuses 10 in a comparable manner.

For example, in the mass production operation, it is important that the substrate processing apparatuses 10 operate without waste as much as possible. For this reason, when there is a substrate processing apparatus 10 in a poor operation status among the substrate processing apparatuses 10 performing the mass production operation, improvement is required as soon as possible.

For example, in the chart 2002 of FIG. 15, for three substrate processing apparatuses 10 performing production according to a recipe, it is possible to easily compare time zones of the state “Depo”. Then, the substrate processing apparatus “BBB” in a poor operation status is easy to find because it has a longer time for the state “Depo” than the substrate processing apparatuses “AAA” and “CCC” performing production according to the same recipe.

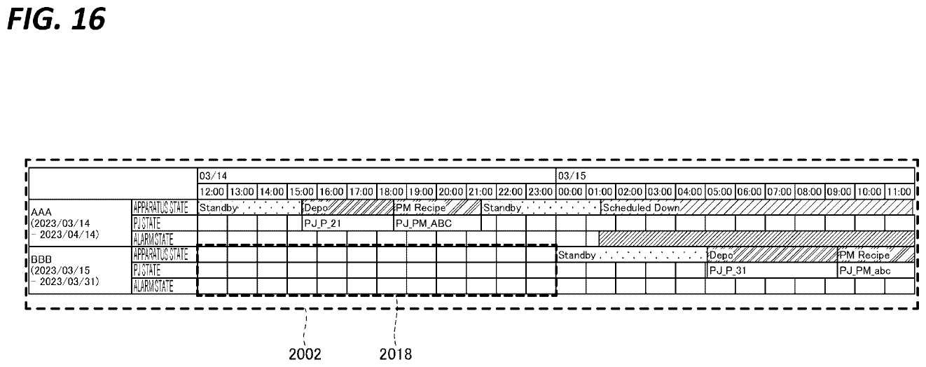

Also, when different periods are specified for the substrate processing apparatuses 10, as illustrated in the chart 2002 of FIG. 16, the display control unit 40 of the operator terminal 18 displays information for each specified period. For the second substrate processing apparatus 10 in the chart 2002 of FIG. 16, no information is displayed in an area 2018 because 3/14 is outside the specified period.

### Apparatus Deletion

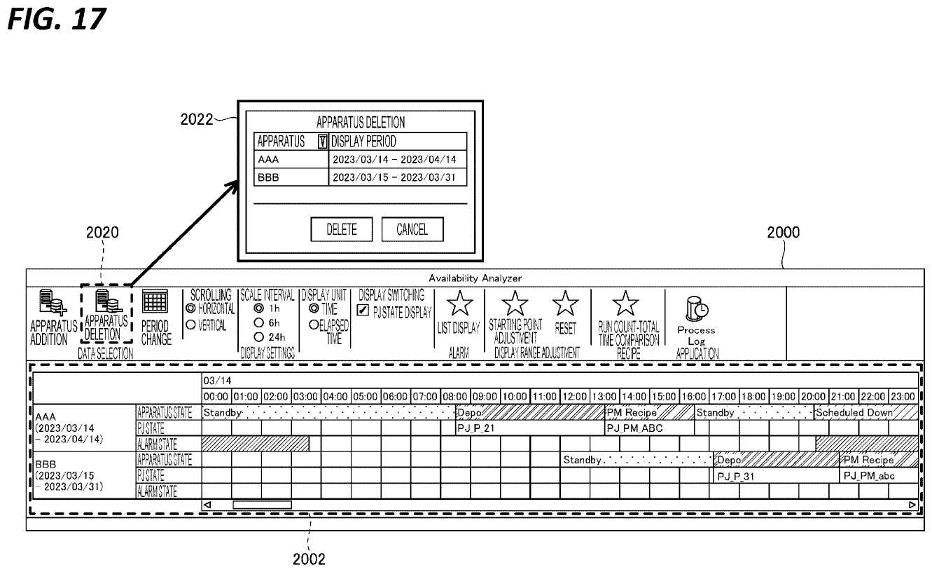

The operator operates an apparatus deletion button 2020 on the operation analysis screen 2000 in FIG. 17, thereby displaying an apparatus deletion field 2022. The operator may delete the substrate processing apparatus 10 displayed in the chart 2002, from the apparatus deletion field 2022.

FIG. 17 is a view illustrating an example of apparatus deletion. The display control unit 40 of the operator terminal 18 displays the apparatus deletion field 2022 by receiving the operation on the apparatus deletion button 2020 from the operator. Also, when the substrate processing apparatus 10 to be deleted is selected from the apparatus deletion field 2022, the display control unit 40 may delete the substrate processing apparatus 10 selected by the operator, from the chart 2002.

### Period Change

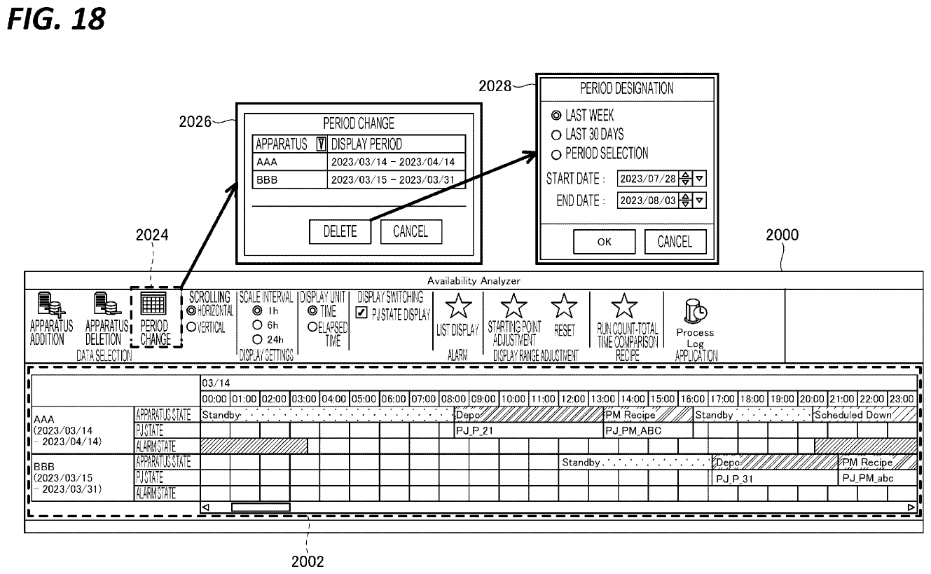

The operator operates a period change button 2024 on the operation analysis screen 2000 of FIG. 18, thereby displaying a period change field 2026. The operator selects the substrate processing apparatus 10 for which the period is to be changed, from the period change field 2026, thereby displaying a period designation field 2028. Then, the period may be changed.

FIG. 18 is a view illustrating an example of a period change. The display control unit 40 of the operator terminal 18 displays the period change field 2026 by receiving the operation on the period change button 2024 from the operator. Also, when the substrate processing apparatus 10 for which the period is to be changed is selected from the period change field 2026, the display control unit 40 displays the period designation field 2028 in which the period of the substrate processing apparatus 10 selected by the operator is to be specified. When the period is specified in the period designation field 2028, the display control unit 40 may change the period in the chart 2002 for the substrate processing apparatus 10 selected by the operator.

### Starting Point Adjustment

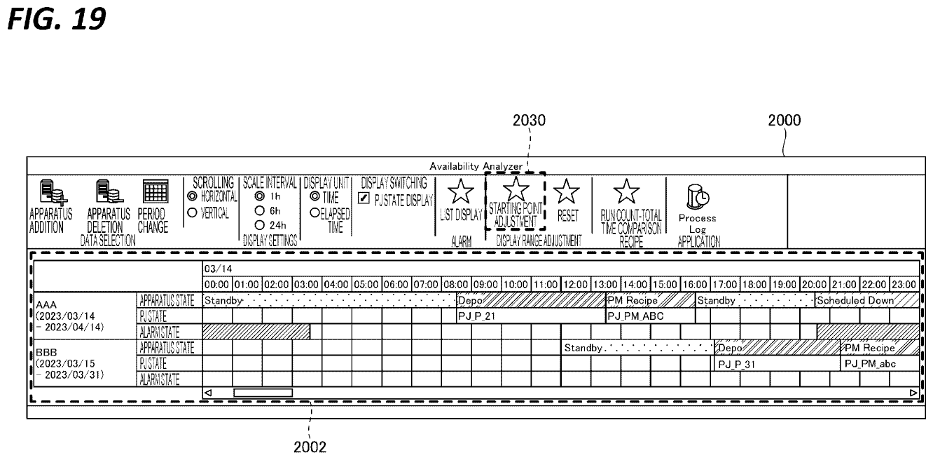

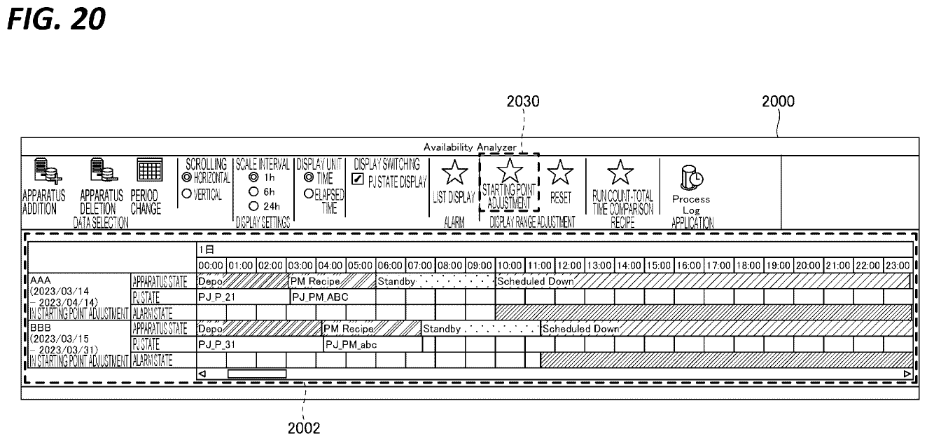

As in the chart 2002 of the operation analysis screen 2000 in FIG. 19, when the plurality of substrate processing apparatuses 10 is displayed, the operator may select targets for starting point adjustment and operate a starting point adjustment button 2030, so that the starting point adjustment may be performed as in the chart 2002 of the operation analysis screen 2000 in FIG. 20.

FIG. 19 and FIG. 20 are views illustrating an example of starting point adjustment. The operator may place, for example, a cursor on the starting point adjustment targets in the chart 2002 of the operation analysis screen 2000 of FIG. 19 and perform clicking so as to select the starting point adjustment targets.

For example, the operator selects time zones of the state “Depo” of the substrate processing apparatuses “AAA” and “BBB” from the chart 2002 in FIG. 19, as starting point adjustment targets. In a state where the time zones of the state “Depo” of the substrate processing apparatuses “AAA” and “BBB” are selected from the chart 2002 in FIG. 19, as the starting point adjustment targets, the operator may operate the starting point adjustment button 2030 so as to perform the starting point adjustment as in the chart 2002 of the operation analysis screen 2000 of FIG. 20.

The display control unit 40 of the operator terminal 18 adjusts a display range such that a starting point is set to the time zones of the state “Depo” of the substrate processing apparatuses “AAA” and “BBB” selected from the chart 2002 as the starting point adjustment targets, so as to display the chart 2002 of FIG. 20.

Even when periods in the history information of the substrate processing apparatuses 10 are different, through the starting point adjustment illustrated in FIG. 19 and FIG. 20, the operator may display the charts 2002 of the substrate processing apparatuses 10 side by side in a comparable manner by setting the display unit to the “elapsed time.”

Also, through the starting point adjustment illustrated in FIG. 19 and FIG. 20, the operator may specify starting point adjustment targets, and then, after the starting point adjustment, the charts 2002 of the substrate processing apparatuses 10 may be displayed side by side in a comparable manner. After the starting point adjustment is performed, by checking the charts 2002, the operator may easily grasp the difference in the timing at which the apparatus state is switched. The starting point adjustment targets are not limited to the time zones of the state “Depo,” and may be, for example, the time zones of the state “PM Recipe.”

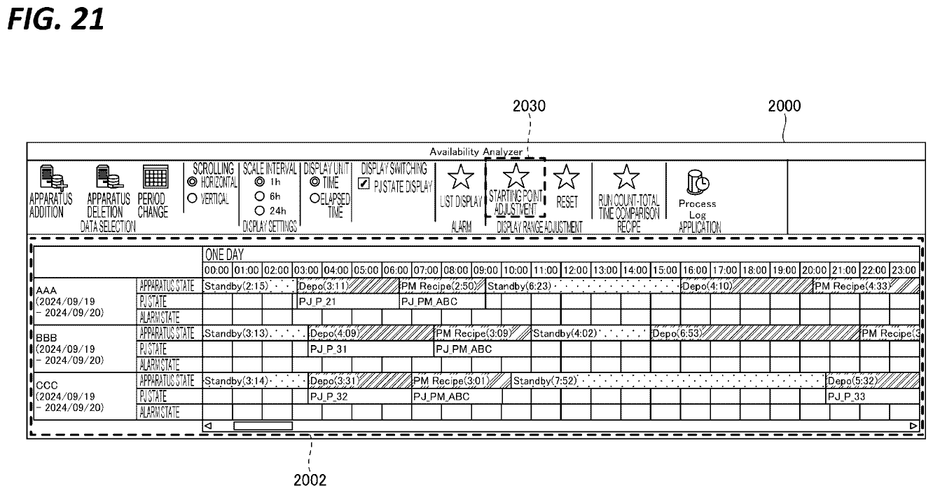

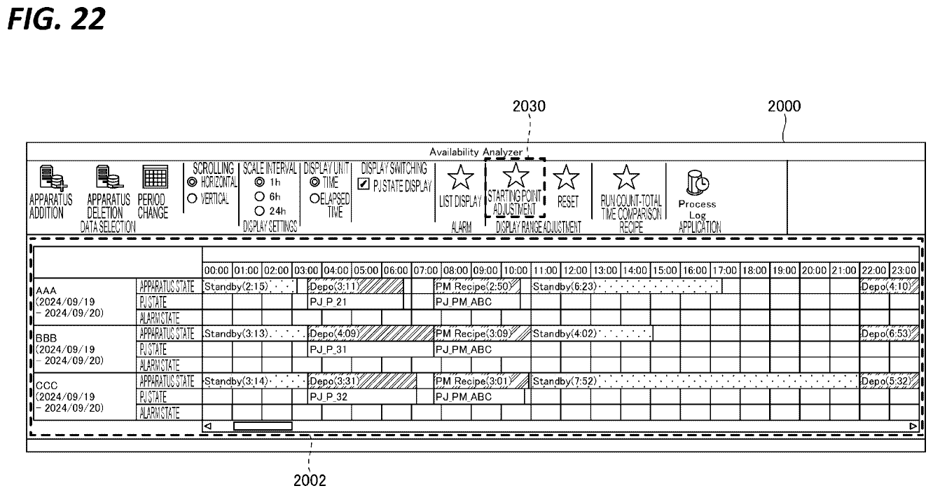

Also, in the starting point adjustment illustrated in FIG. 20, the display range is adjusted such that the starting point is set to the starting point adjustment targets selected from the chart 2002 of FIG. 19. The starting point adjustment described by using FIG. 19 and FIG. 20 may be performed as illustrated in, for example, FIG. 21 and FIG. 22.

FIG. 21 and FIG. 22 are views illustrating an example of starting point adjustment. As in FIG. 20, in FIG. 21, the display range is adjusted such that the starting point is set to starting point adjustment targets selected from the chart 2002.

In FIG. 22, the starting point adjustment is performed for each apparatus state as well as starting point adjustment targets selected from the chart 2002. Since the starting point adjustment illustrated in FIG. 22 is performed for each apparatus state, it is easy for the operator to compare lengths of time for each apparatus state.

The chart 2002 displayed in FIG. 22 is different from the actual one, because a blank space, which is not actually there, is present between apparatus states. However, since starting point adjustment is performed for each apparatus state, the operator may easily intuitively compare the lengths of time for each apparatus state.

According to the chart 2002 of FIG. 22, when operation statuses of the substrate processing apparatuses 10 are displayed in a comparable manner, the starting point adjustment (head alignment) is performed for each apparatus state. Thus, it is possible to check the difference in the length of time for each apparatus state, between the substrate processing apparatuses 10, at a glance. Also, according to the chart 2002 of FIG. 22, since the difference in the length of time for each apparatus state between the substrate processing apparatuses 10 may be grasped at a glance, it is easy to grasp an improvement point of the substrate processing apparatus 10 in the mass production operation.

The process returns to the step S18 of FIG. 4, and the input reception unit 38 of the operator terminal 18 determines whether a new operation has been received from the operator. When a new operation is received from the operator, the operator terminal 18 returns to the step S16 and continues to perform processing.

When a new operation is not received from the operator, the process proceeds to the step S20 and the input reception unit 38 of the operator terminal 18 determines whether a display ending operation of the operation analysis screen 2000 has been received from the operator. When a display ending operation of the operation analysis screen 2000 is not received from the operator, the operator terminal 18 returns to the step S18. When a display ending operation of the operation analysis screen 2000 is received from the operator, the processing of the flowchart of FIG. 4 is ended.

The operator terminal 18 may display the timings at which the states of the substrate processing apparatus 10 are switched in the chart 2002, in chronological order, on the operation analysis screen 2000. Also, since process execution timings differ among the substrate processing apparatuses 10, the chart 2002 may be displayed such that differences may be easily understood by the starting point adjustment.

In the substrate processing system 1 according to the present embodiment, the apparatus states of the substrate processing apparatus 10 are displayed such that the operation status of the substrate processing apparatus 10 may be easily checked through the above-mentioned chart 2002 displayed on the operation analysis screen 2000. Thus, it is possible to improve ease in checking the operation status of the substrate processing apparatus 10.

Also, in the substrate processing system 1 according to the present embodiment, in the mass production operation, it becomes easier to identify the problematic portion of the substrate processing apparatus 10 that is poorly operating, and thus an improvement in the operation rate may be expected. As a result, according to the substrate processing system 1 of the present embodiment, production loss may be suppressed.

The substrate processing apparatus 10 of the present disclosure may be applied to any type of apparatus among an atomic layer deposition (ALD) apparatus, capacitively coupled plasma (CCP), inductively coupled plasma (ICP), a radial line slot antenna (RLSA), electron cyclotron resonance plasma (ECR), and helicon wave plasma (HWP). The substrate processing apparatus 10 of the present disclosure is also applicable to a chemical vapor deposition (CVD) apparatus or an oxidation/annealing apparatus.

The substrate processing system 1 of the present disclosure is not limited to the configuration illustrated in FIG. 1, and it goes without saying that there are various system configuration examples depending on the use and purpose. The substrate processing apparatus 10 of the present disclosure may also be applied to any one of a single-wafer apparatus that processes substrates one by one, a batch apparatus that processes a plurality of substrates at once, and a semi-batch apparatus. Examples of the process performed by the substrate processing apparatus 10 of the present disclosure may include film forming processing and etching processing.

According to the present disclosure, it is possible to provide a technique for improving ease in checking the operation status of the substrate processing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus that displays operation statuses of one or more substrate processing apparatuses, the information processing apparatus comprising:
acquisition circuitry configured to acquire history information of a plurality of apparatus states to which the plurality of substrate processing apparatuses have transitioned; and
display control circuitry configured to display time zones during which the plurality of substrate processing apparatuses were in the apparatus states, in chronological order, based on the history information acquired by the acquisition circuitry such that each of the plurality of apparatus states is identifiable.

2. The information processing apparatus according to claim 1, wherein the plurality of apparatus states includes at least a state where a substrate processing apparatus performs production according to a recipe.

3. The information processing apparatus according to claim 1, wherein the display control circuitry display time zones during which the plurality of substrate processing apparatuses were in the plurality of apparatus states to be comparable among the substrate processing apparatuses.

4. The information processing apparatus according to claim 1, wherein the display control circuitry display time zones of one apparatus state selected by an operator among the plurality of apparatus states, in chronological order according to a starting point.

5. The information processing apparatus according to claim 4, wherein the display control circuitry display time zones during which the substrate processing apparatuses were in the apparatus states by matching starting points of the plurality of substrate processing apparatuses for each of the plurality of apparatus states.

6. The information processing apparatus according to claim 1, wherein the acquisition circuitry acquire history information of states of alarms occurred in the plurality of substrate processing apparatuses, and
the display control circuitry display time zones during which the alarms were occurring in the plurality of substrate processing apparatuses in chronological order, based on the history information acquired by the acquisition circuitry.

7. The information processing apparatus according to claim 1, wherein the acquisition circuitry acquire history information of process job states of the plurality of substrate processing apparatuses, and
the display control circuitry display time zones during which the plurality of substrate processing apparatuses were executing process jobs, in chronological order, based on the history information acquired by the acquisition circuitry such that each of the process jobs is identifiable.

8. The information processing apparatus according to claim 1, wherein the display control circuitry display the time zones during which the plurality of substrate processing apparatuses were in the plurality of apparatus states, by time or elapsed time.

9. An information processing method in which an information processing apparatus displays operation statuses of one or more substrate processing apparatuses, the information processing method comprising:
acquiring history information of a plurality of apparatus states to which the plurality of substrate processing apparatuses have transitioned; and
displaying time zones during which the plurality of substrate processing apparatuses were in the plurality of apparatus states, in chronological order, based on the history information acquired in the acquiring such that each of the plurality of apparatus states is identifiable.

10. A non-transitory computer-readable storage medium having stored therein a program that causes an information processing apparatus to execute a process including:
acquiring history information of a plurality of apparatus states to which the plurality of substrate processing apparatuses have transitioned; and
performing a display control in which time zones during which the plurality of substrate processing apparatuses were in the plurality of apparatus states, are displayed in chronological order based on the history information acquired in the acquiring such that each of the plurality of apparatus states is identifiable.
